(19) United States
(12) Patent Application Publication
(10) Pub. No.: US 2014/0118968 A1
(43) Pub. Date: May 1, 2014

(54) ELECTRONIC DEVICE AND ELECTRIC CONNECTOR

(71) Applicant: KABUSHIKI KAISHA TOSHIBA, Tokyo (JP)

(72) Inventor: Akira TANAKA, Tokyo (JP)

(73) Assignee: KABUSHIKI KAISHA TOSHIBA, Tokyo (JP)

(21) Appl. No.: 13/906,190

(22) Filed: May 30, 2013

(30) Foreign Application Priority Data
Oct. 31, 2012 (JP) 2012-240924

(51) Int. Cl. H05K 5/03

(52) U.S. Cl. CPC H05K 5/03
USPC 361/749

(57) ABSTRACT

According to one embodiment, electronic device includes a first casing, second casing, flexible printed circuit board, and pushing member. The board includes: first portion including first end fixed to the first casing and provided along sliding direction of the first casing; second portion including second end fixed to the second casing, provided along the sliding direction, and arranged spaced apart from the first portion; and first folded-back portion connecting end of the first portion and end of the second portion. The pushing member includes: third portion including third end fixed to the first casing, provided along the sliding direction, and overlaid on the first portion; fourth portion including fourth end fixed to the second casing, provided along the sliding direction, and arranged spaced apart from the third portion; and second folded-back portion extending from end of the third portion to end of the fourth portion.

### CROSS-REFERENCE TO RELATED APPLICATIONS

This application is based upon and claims the benefit of priority from Japanese Patent Application No. 2012-240924, filed Oct. 31, 2012, the entire contents of which are incorporated herein by reference.

### FIELD

Embodiments described herein relate generally to an electronic device and an electric connector.

### BACKGROUND

Conventionally, there has been known an electronic device provided with two casings that are slidably connected with each other and a flexible printed circuit board provided across the two casings.

In this type of electronic device, it is desired that inconvenience such as damage hardly occurs in the flexible printed circuit board.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device in an opened state according to a first embodiment;

FIG. 2 is an exemplary perspective view of the electronic device in an overlaid state in the first embodiment;

FIG. 3 is an exemplary sectional side view of the electronic device in the opened state in the first embodiment;

FIG. 4 is an exemplary sectional side view of the electronic device in an intermediate state in the first embodiment;

FIG. 5 is an exemplary sectional side view of the electronic device in the overlaid state in the first embodiment;

FIG. 6 is an exemplary side view of an electric connector of the electronic device in the opened state, in the first embodiment;

FIG. 7 is an exemplary side view of the electric connector of the electronic device in the intermediate state, in the first embodiment;

FIG. 8 is an exemplary side view of the electric connector of the electronic device in the overlaid state, in the first embodiment;

FIG. 9 is an exemplary sectional view taken along the line F9-F9 of FIG. 8, in the first embodiment;

FIG. 10 is an exemplary sectional side view of the electric connector in the first embodiment;

FIG. 11 is an exemplary exploded view of a portion of the electric connector in the first embodiment;

FIG. 12 is an exemplary side view of the portion of the electric connector in the first embodiment;

FIG. 13 is an exemplary sectional view of a portion of an electric connector according to a second embodiment;

FIG. 14 is an exemplary bottom view of a portion of an electric connector according to a third embodiment;

FIG. 15 is an exemplary sectional view of a portion of the electric connector in the third embodiment;

FIG. 16 is an exemplary side view of an electric connector of an electronic device in an opened state according to a fourth embodiment;

FIG. 17 is an exemplary side view of the electric connector of the electronic device in an intermediate state in the fourth embodiment;

FIG. 18 is an exemplary side view of the electric connector of the electronic device in an overlaid state, in the fourth embodiment;

FIG. 19 is an exemplary exploded view of a portion of the electric connector in the fourth embodiment;

FIG. 20 is an exemplary view of a portion of an electric connector as viewed from a sliding direction, according to a fifth embodiment; and

FIG. 21 is an exemplary exploded view of a portion of the electric connector in the fifth embodiment.

### DETAILED DESCRIPTION

In general, according to one embodiment, an electronic device comprises: a first casing; a second casing; a first flexible printed circuit board; and a pushing member. The first casing comprises a first electronic component. The second casing comprises a second electronic component. The first casing is configured to be slidably connected to the second casing. The first flexible printed circuit board comprises: a first end; a second end; a first extending portion; a second extending portion; and a first folded-back portion. The first end is fixed to the first casing and configured to be electrically connected to the first electronic component. The second end is fixed to the second casing and configured to be electrically connected to the second electronic component. The first extending portion comprises the first end and is provided along a sliding direction of the first casing with respect to the second casing. The second extending portion comprises the second end, is provided along the sliding direction, and is arranged spaced apart from the first extending portion. The first folded-back portion is with a curved shape, and is configured to connect an end of the first extending portion opposite the first end and an end of the second extending portion opposite the second end with each other. The pushing member comprises: a third end; a fourth end; a third extending portion; a fourth extending portion; and a second folded-back portion. The third end is fixed to the first casing. The fourth end is fixed to the second casing. The third extending portion comprises the third end, is provided along the sliding direction, and is overlaid on the first extending portion at a side of the first extending portion opposite the second extending portion. The fourth extending portion comprises the fourth end, is provided along the sliding direction, and is arranged spaced apart from the third extending portion. The second folded-back portion is with a curved shape, and extends from an end of the third extending portion opposite the third end to an end of the fourth extending portion opposite the fourth end in a direction away from the first folded-back portion.

Hereinafter, embodiments will be described in detail with reference to the drawings. A plurality of embodiments below comprise similar elements. Therefore, those similar elements will be referred to below by common reference numerals, and a redundant description will be omitted.

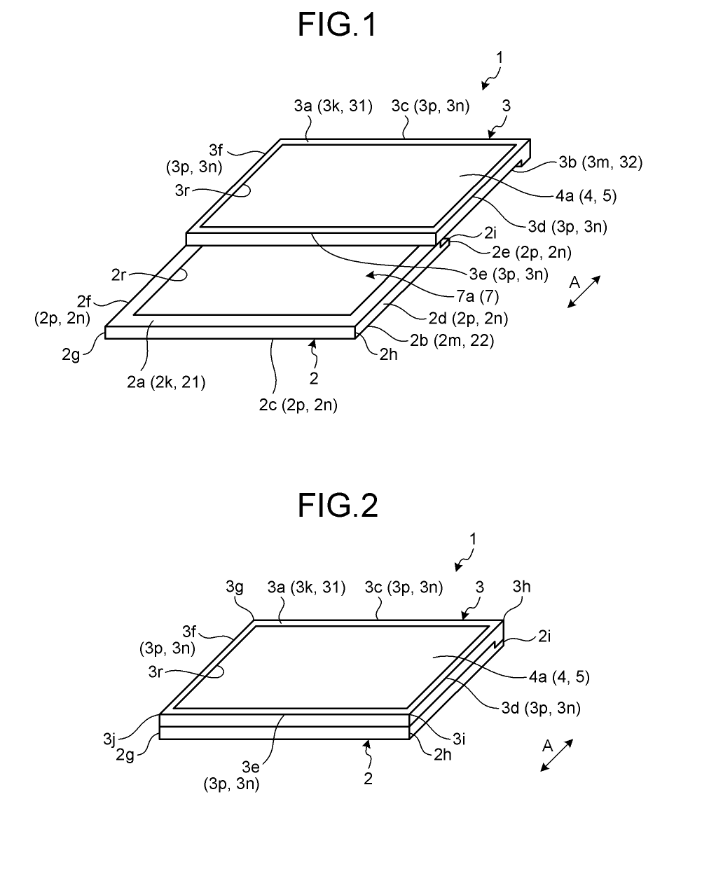

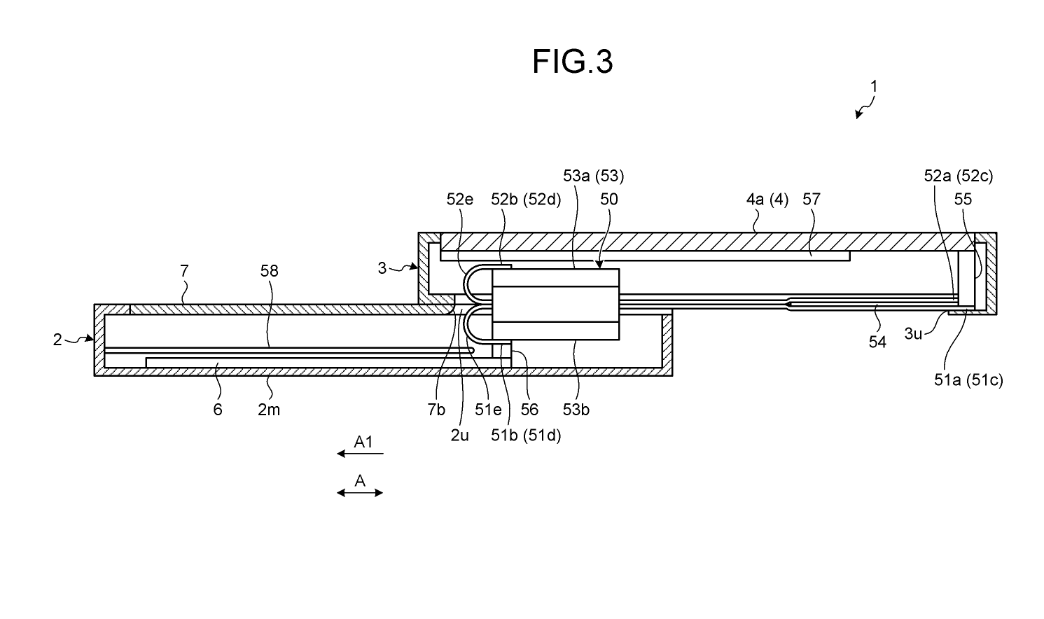

In the present embodiment, as an example, as illustrated in FIGS. 1 and 2, an electronic device 1 comprises a first casing 3 and a second casing 2. The first casing 3 houses at least a portion of a display device 4 (a first electronic component). The second casing 2 houses a circuit board 6 (a second electronic component, see FIG. 3). The second casing 2 includes a keyboard (an input operation module, input receiver, or input module) and the like.

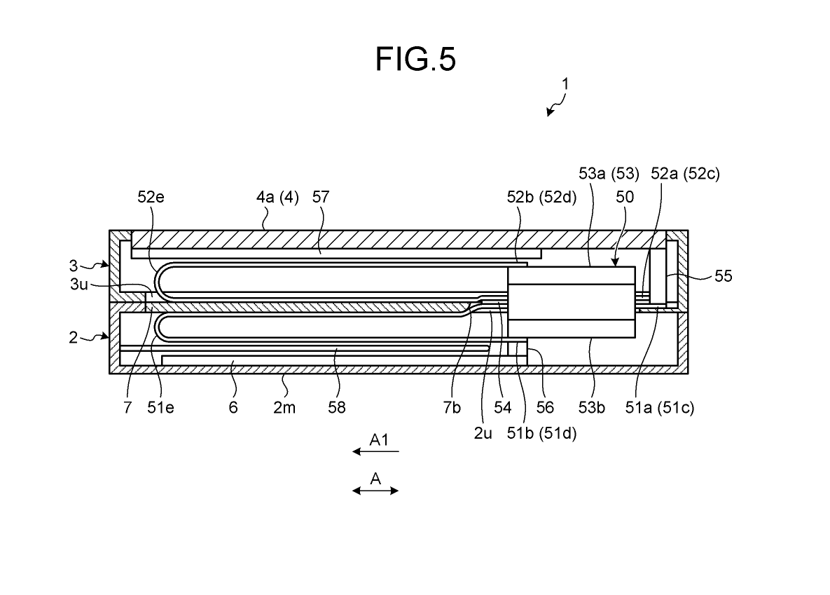

The first casing 3 and the second casing 2 are slidably (movably) connected by a coupling mechanism (a connector, coupler, connecting mechanism, or support mechanism). In other words, the first casing 3 is slidably connected to the second casing 2. The first casing 3 and the second casing 2 are slidably coupled with respect to each other by the connecting mechanism between an opened state illustrated in FIGS. 1 and 3 and an overlaid state illustrated in FIGS. 2 and 5. In other words, the second casing 2 slidably supports the first casing 3 through the coupling mechanism.

In the present embodiment, as an example, a display screen 4a of the display device 4 is exposed through an opening 3r provided on a surface 3a (a front surface, front, first surface, or first surface part) of the first casing 3. A keyboard 7 is exposed on a surface 2a (an upper surface, front, first surface, or first surface portion) of the second casing 2. In the overlaid state, a surface 3b on the side opposite the surface 3a of the first casing 3 and the surface 2a of the second casing 2 are overlaid to cover the keyboard 7 with the first casing 3. In the opened state, the surface 2a of the second casing 2 is exposed, making the keyboard 7 available (operable).

The first casing 3 is, in the present embodiment, as an example, formed to have a rectangular-like shape (in the present embodiment, a rectangular shape as an example) in the front view and the back view. The first casing 3 is, in the present embodiment, as an example, formed in a flat rectangular parallelepipedal shape that is thin in the longitudinal direction. The first casing 3 comprises the surface 3a (the front surface, front, first surface, or first surface portion) and the surface 3b (the rear surface, back surface, second surface, or second surface portion) opposite the surface 3a. The surface 3a and the surface 3b are substantially parallel to each other. The first casing 3 comprises, in the front view, four ends 3c to 3f (sides or edges) and four corners 3g to 3j (pointed portions, bent portions, or ends). The ends 3c and 3e are examples of long sides, whereas the ends 3d and 3f are examples of short sides.

The first casing 3 comprises a wall 3k (a first part, plate, frame, front wall, surface wall, or top wall) comprising the surface 3a, and a wall 3m (a second part, plate, rear wall, back wall, or bottom wall) comprising the surface 3b. The walls 3k and 3m are formed to have a rectangular-like shape (in the present embodiment, a rectangular shape, as an example). The first casing 3 comprises four walls 3n (third parts, plates, side walls, end walls, upright walls, or crossing portions) having a surface 3p (a side surface, peripheral surface, or third surface) across the wall 3k and the wall 3m. The wall 3k has, as an example, the opening 3r formed in a rectangular shape. The wall 3k is therefore formed in a rectangular and frame shape.

The first casing 3 may be formed by combining a plurality of components (split bodies). The first casing 3 comprises, in the present embodiment, as an example, a first casing member 31 (a first part, front member, mask, mask portion, cover, front cover, cover portion, or first area) comprising at least the wall 3k, and a second casing member 32 (a second part, rear member, base, base portion, bottom, bottom portion, cover, rear cover, cover portion, or second area) comprising at least the wall 3m. At least either one of the first casing member 31 and the second casing member 32 (for example, the second casing member 32) comprises the wall 3n. The first casing 3 may comprise, apart from the first casing member 31 and the second casing member 32, a third casing member (a third part, intermediate member, partition member, barrier member, wall member, an intervening member, inner plate, middle plate, middle frame, or a third area, which is not illustrated) and a fourth casing member (a fourth part, intermediate member, partition member, barrier member, wall member, intervening member, cover member, shield, or a fourth area, which is not illustrated), which are positioned in between the first casing member 31 and the second casing member 32.

The first casing 3 may be formed of a metallic material, a synthetic resin material, or the like. The first casing member 31 and the second casing member 32 may be formed of a material with a relatively low rigidity (a material with lower rigidity than that of the third casing member and the fourth casing member, for example, a synthetic resin material). A wall such as a rib (a projecting portion or projecting wall, which is not illustrated) may be provided on the inside of the first casing 3 of the first casing member 31 and the second casing member 32. The wall tends to enhance the rigidity of the first casing 3.

In the present embodiment, as an example, as illustrated in FIGS. 1 and 2, the display screen 4a provided on the surface 3a side of the display device (a display module, display, or panel) is exposed on the front (outside) of the first casing 3, which allows a user to visually recognize the display screen 4a through the opening 3r. The display device 4 is formed to have a rectangular-like shape (in the present embodiment, a rectangular shape as an example) in the front view. The display device 4 is, for example, a liquid crystal display (LCD) or an organic electro-luminescent display (OELD).

In the present embodiment, as an example, an input operational panel 5 (as an example, a touch panel, touch sensor, or operational surface) is provided on the front side (the surface side, wall 3k side) of the display device 4. The input operational panel 5 is formed in a transparent and relatively thin rectangular shape and covers the display screen 4a. An operator (a user or the like) can perform input processing through operations such as touching, pressing, and rubbing the input operational panel 5 with fingers or a part (for example, a stylus, not illustrated) and moving fingers, a stylus, or the like in the vicinity of the input operational panel 5. Lights emitted from the display screen 4a of the display device 4 pass through the input operational panel 5 and exit from the opening 3r of the wall 3k toward the front (outside) of the first casing 3. The input operational panel 5 is an example of the input unit.

The second casing 2 is, in the present embodiment, as an example, as illustrated in FIGS. 1 and 2, formed to have a rectangular-like shape (in the present embodiment, a rectangular shape as an example). The second casing 2 is, in the present embodiment, as an example, formed in a flat rectangular parallelepipedal shape that is thin in the longitudinal direction. The second casing 2 comprises the surface 2a (the upper surface, front, first surface, or first surface portion) and the surface 2b (the lower surface, back surface, second surface, or second surface portion) opposite the surface 2a. The surface 2a and the surface 2b are substantially parallel to each other. The second casing 2 comprises, in the front view, four ends 2c to 2f (sides or edges) and four corners 2g to 2i (pointed portions, bent portions, or ends (one of which is not illustrated)). The ends 2c and 2e are examples of long sides, whereas the ends 2d and 2f are examples of short sides. The end 2e is positioned on the far side in the depth direction (the longitudinal direction), and the end 3c is positioned on the near side.

The second casing 2 comprises a wall 2k (a first part, plate, frame, a front wall, surface wall, or top wall) comprising the surface 2a, and a wall 2m (a second part, plate, rear wall, back wall, bottom wall, see FIG. 3) comprising the surface 2b. The walls 2k and 2m are formed in a rectangular shape (in the present embodiment, a rectangular shape as an example). The second casing 2 comprises four walls 2n (a third part, plate, side wall, end wall, upright wall, or crossing portion) comprising a surface 2p (a side surface, peripheral surface, or third surface) across the wall 2k and the wall 2m. The wall 2k is therefore formed to have a rectangular-like and frame shape.

Furthermore, the second casing 2 may be formed by combining a plurality of components (split bodies). The second casing 2 comprises, in the present embodiment, as an example, a first casing member 21 (a first part, front member, mask, mask part, cover, front cover, cover portion, or first area) comprising at least the wall 2k, and a second casing member 22 (a second part, rear member, base, base portion, bottom, bottom portion, cover, rear cover, cover portion, or second area) comprising at least the wall 2m. At least either one of the first casing member 21 and the second casing member 22 (for example, the second casing member 22) comprises the wall 2n. The second casing 2 may comprise, apart from the first casing member 21 and the second casing member 22, a third casing member (a third part, intermediate member, partition member, barrier member, wall member, an intervening member, inner plate, middle plate, middle frame, or a third area, which is not illustrated) and a fourth casing member (a fourth part, intermediate member, partition member, barrier member, wall member, an intervening member, cover member, shield, or a fourth area, which is not illustrated), which are positioned in between the first casing member 21 and the second casing member 22.

The second casing 2 maybe formed of a metallic material, a synthetic resin material, or the like. The first casing member 21 and the second casing member 22 may be formed of a material with a relatively low rigidity (a material with lower rigidity than that of the third casing member and the fourth casing member, for example, a synthetic resin material). A wall such as a rib (a projecting portion or projecting wall, which is not illustrated) may be provided on the inside of the second casing 2 of the first casing member 21 and the second casing member 22. The wall tends to enhance the rigidity of the second casing 2.

In the present embodiment, as an example, as illustrated in FIGS. 1 and 2, an operational surface 7a (a surface or upper surface) of the keyboard 7 is exposed toward the front (outside) of the second casing 2 through an opening 2r.

In the present embodiment, as an example, as illustrated in FIGS. 3 to 5, the second casing 2 houses a circuit board 6 (a board, control board, main board, electronic component, second electronic component, electric component, or second electric component) in the rear side (the back side, the side behind, the wall 2m side, or the side opposite the operational surface 7a) of the keyboard 7. The circuit board 6 is provided parallel to the keyboard 7. The circuit board 6 is fixed to the wall 2m.

In the present embodiment, as an example, the circuit board 6 can be mounted with a plurality of components (not illustrated) such as a central processing unit (CPU), a graphic controller, a power source circuit component, a platform controller hub (PCH), a memory slot connector, an LCD connector, an input/output (I/O) connector, a power source coil, an element, and a connector. A control circuit may comprise, for example, a video signal processing circuit, a tuner, a high-definition multimedia interface (HDMI) signal processing unit, an audio video (AV) input terminal, a remote-control signal receiver, a controller, a selector, an on-screen display interface, a storage module (for example, a read-only memory (ROM), a random access memory (RAM), a hard disc drive (HDD), and a solid state drive (SSD)), and a voice signal processing circuit. The control circuit controls video (moving image, still image, and the like) output by the display screen 4a of the display device 4, voice output by a speaker (not illustrated), light emission by a light emitting diode (LED, not illustrated), and the like. The display device 4, the speaker, the LED, and the like are examples of an output module.

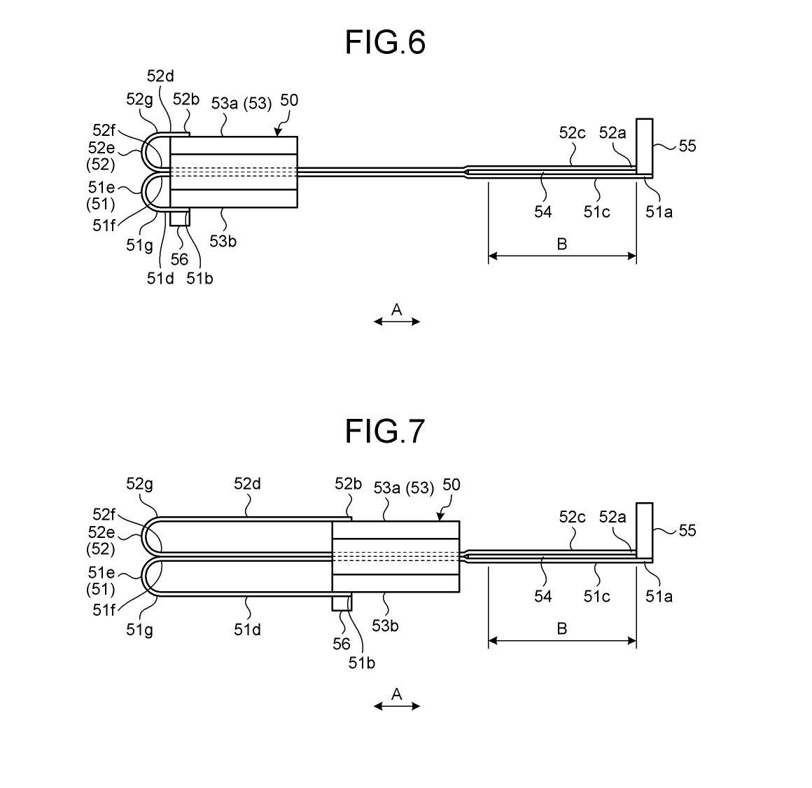

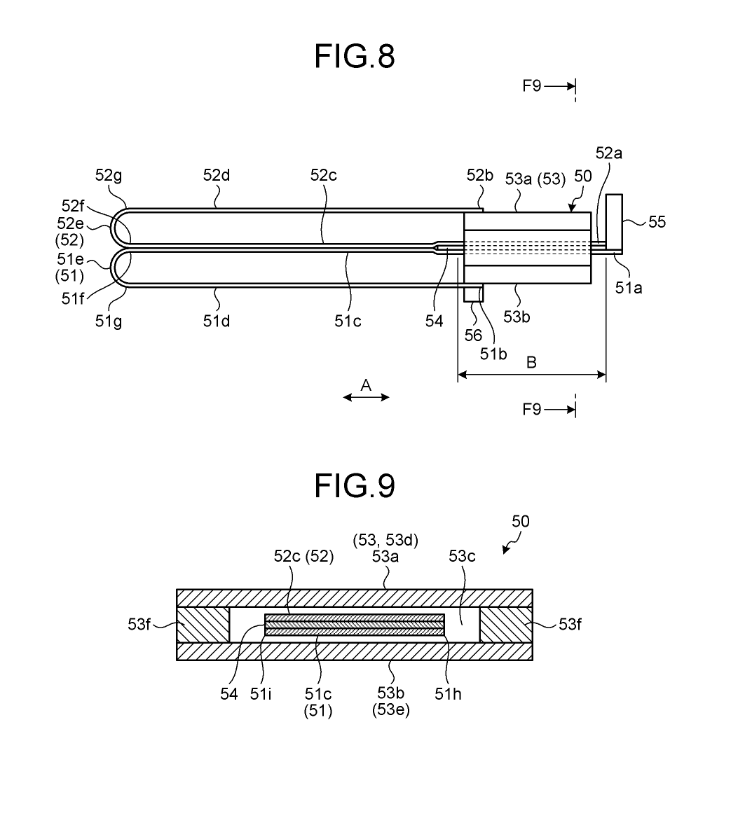

In the present embodiment, as an example, as illustrated in FIGS. 3 to 5, the electronic device 1 is provided with an electric connector 50. The electric connector 50 comprises, as illustrated in FIGS. 6 to 8, printed circuit boards 51 and 52 having flexibility (elasticity), and a fixing member 53 to which the flexible printed circuit boards 51 and 52 are fixed. The flexible printed circuit board 51 (a first flexible printed circuit board) electrically connects the display device 4 and the circuit board 6. The flexible printed circuit board 52 (a second flexible printed circuit board, pushing member, support member, weight member, or member) is formed in a shape that is substantially symmetric with the flexible printed circuit board 51, and is overlaid on the flexible printed circuit board 51 to press the flexible printed circuit board 51. As an example, the flexible printed circuit board 52 is a dummy and is not electrically connected to the electronic component. A plate member 54 is provided in between the flexible printed circuit boards 51 and 52. The first casing 3 and the second casing 2 have openings 3u and 2u in which a portion of the electric connector 50 is positioned. FIGS. 6 to 8, 11, and 12 illustrate the state of the electric connector 50 when the electric connector 50 is not incorporated into the electronic device 1, for convenience.

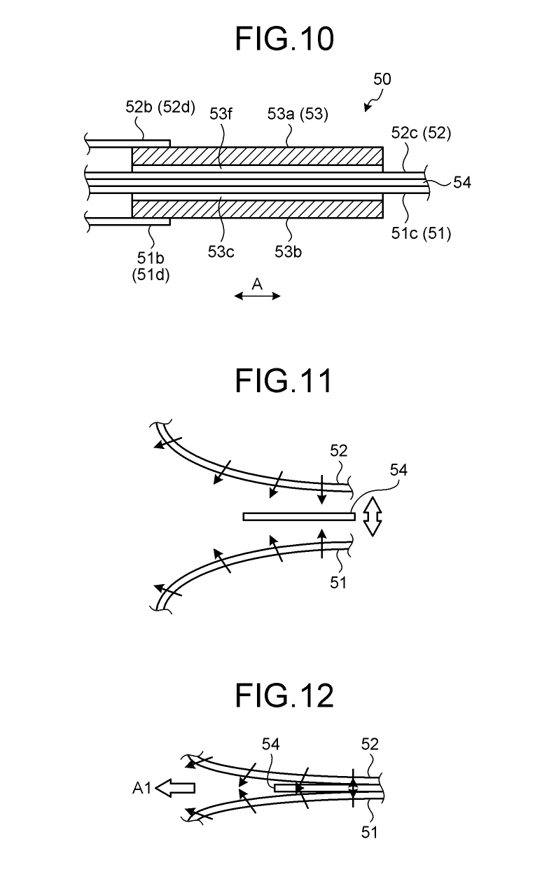

The fixing member 53 (a component or core) is, as illustrated in FIGS. 9 and 10, formed in a tubular shape. The fixing member 53 is fixed to the second casing 2. The fixing member 53 is, as an example, fixed to the wall 2m through a fixing portion (not illustrated). The fixing member 53 comprises surfaces (outer surfaces) 53a and 53b. The surface 53a is positioned within the first casing 3, and the surface 53b is positioned within the second casing 2. The fixing member 53 has a hole 53c. The hole 53c passes through the fixing member 53 in the sliding direction A of the first casing 3 with respect to the second casing 2. An extending portion 51c of the flexible printed circuit boards 51 and an extending portion 52c of the flexible printed circuit boards 52, both of which will be described later, are passed through the hole 53c. A gap is provided in between an inner periphery 53g of the hole 53c and the extending portions 51c and 52c.

The fixing member 53 may be formed by combining a plurality of components (divided bodies). In the present embodiment, as an example, the fixing member 53 comprises a first member 53d comprising a surface 53a, a second member 53e that is provided spaced apart from the first member 53d and comprises a surface 53b, and a spacer 53f that is provided in between the first member 53d and the second member 53e. The first member 53d, the second member 53e, and the spacer 53f are connected to each other through, for example, adhesion and welding. The fixing member 53 may be formed of a one-piece component. The fixing member 53 may be formed of resin, metal, glass, or the like.

The flexible printed circuit board 51 is formed to have a sheet-like shape. The flexible printed circuit board 51 comprises two ends 51a and 51b in the longitudinal direction thereof. The flexible printed circuit board 51 comprises, as an example, terminals provided at both ends 51a and 51b, a conductor provided across the terminals, a base provided with the conductor and the terminals, and a cover that covers the conductor.

The end 51a is, as an example, positioned within the first casing 3. The end 51a (a first end) is fixed to the first casing 3 and is electrically connected to the display device 4. As an example, the end 51a is connected to a connector 55 (a first connector) provided to the display device 4. The end 51a is provided with a terminal (a first terminal) that is electrically connected to the connector 55. The end 51a is thus, as an example, fixed to the first casing 3 through the display device 4 (the connector 55).

The end 51b (a second end) is, as an example, positioned within the second casing 2. The end 51b is fixed to the second casing 2 and is electrically connected to the circuit board 6. The end 51b is connected to a connector 56 (a second connector) provided to the circuit board 6. The end 51b is connected to the surface 53b of the fixing member 53 through, for example, adhesion. The end 51b is thus, as an example, fixed to the second casing 2 through the fixing member 53 and the circuit board 6 (the connector 56).

The flexible printed circuit board 51 comprises, as an example, the two extending portions 51c and 51d and a folded-back portion 51e that is provided in between the extending portions 51c and 51d.

The extending portion 51c (a first extending portion or a first sheet) comprises the end 51a and is provided along (extended in) a sliding direction A of the first casing 3 with respect to the second casing 2. The extending portion 51d (a second extending portion or a second sheet) comprises the end 51b and is provided along (extended in) the sliding direction A of the first casing 3.

The extending portion 51d is arranged spaced apart from the extending portion 51c. The extending portion 51d is positioned within the second casing 2. The folded-back portion 51e (a first folded-back portion or a first curved portion) connects an end 51f of the extending portion 51c opposite the end 51a and an end 51g of the extending portion 51d opposite the end 51b with each other.

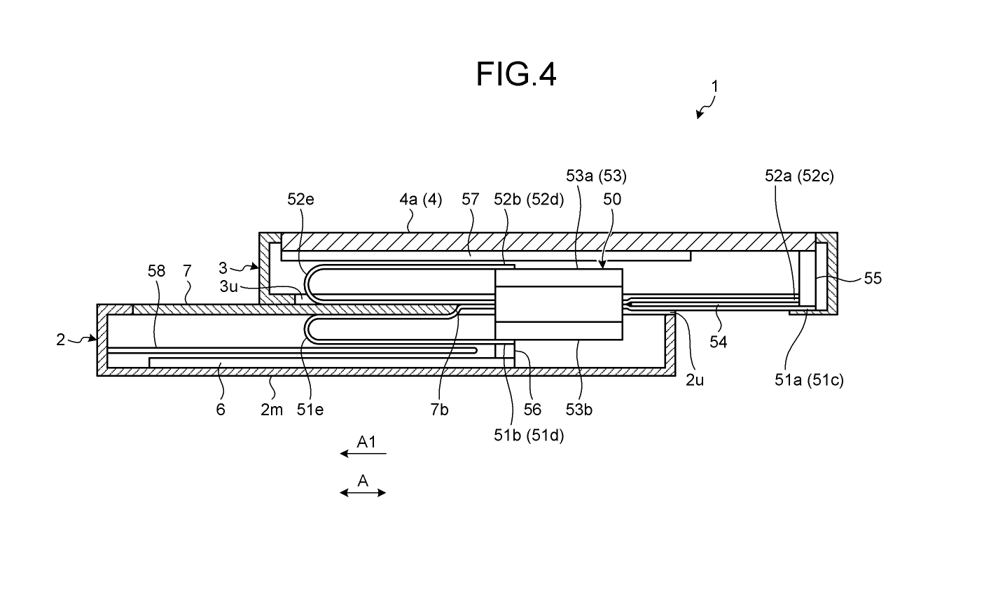

The folded-back portion 51e is formed in a curved shape. In the flexible printed circuit board 51, as illustrated in FIGS. 4 to 6, the folded-back portion 51e moves in the sliding direction A through the slide of the first casing 3.

The flexible printed circuit board 52 is formed to have a sheet-like shape. The flexible printed circuit board 52 comprises, as an example, two ends 52a and 52b in the longitudinal direction. The ends 52a and 52b are each provided with a terminal. The ends 52a and 52b are positioned within the first casing 3. The end 52a (a third end) is fixed to the first casing 3. As an example, the end 52a is fixed to the flexible printed circuit board 51 through the plate member 54 and is fixed to the connector 55 through adhesion or the like. In the present embodiment, therefore, the end 52a is fixed to the first casing 3 through the display device 4. The end 52b (a fourth end) is fixed to the second casing 2. As an example, the end 52b is fixed to the surface 53a of the fixing member 53 through adhesion or the like. In other words, the end 52b is fixed to the second casing 2 through the fixing member 53.

The flexible printed circuit board 52 comprises, as an example, the two extending portions 52c and 52d and a folded-back portion 52e positioned in between the extending portions 52c and 52d.

The extending portion 52c (a third extending portion or a third sheet) comprises the end 52a. The extending portion 52c is provided along (extended in) the sliding direction A of the first casing 3. The extending portion 52c is overlaid on the extending portion 51c at a side opposite the extending portion 51d. Specifically, at least portion of the third extending portion 52c is overlaid on the extending portion 51c at a side opposite the extending portion 51d with the plate member 54 interposed therebetween. A portion of the extending portion 52d is fixed to the extending portion 51d. The fixing range B of the extending portion 52d and the extending portion 51d is, as an example, a particular range starting from the end 52a in which the folded-back portions 51e and 52e are not positioned. The flexible printed circuit board 52 functions, as an example, as a reinforcing member for the flexible printed circuit board 51.

The extending portion 52d (a fourth extending portion or a fourth sheet) comprises the end 52b. The extending portion 52d is provided along (extended in) the sliding direction A of the first casing 3. The extending portion 52d is arranged spaced apart from the extending portion 52c.

The folded-back portion 52e (a second folded-back portion) extends from an end 52f of the extending portion 52c opposite the end 52a to an end 52g of the extending portion 52d opposite the end 52b in a direction away from the folded-back portion 51e. The folded-back portion 52e is formed in a curved shape. The folded-back portion 52e is positioned at nearly the same position as the folded-back portion 51e in the sliding direction A. The folded-back portion 52e and the folded-back portion 51e have nearly a symmetric shape.

The folded-back portion 52e of the flexible printed circuit board 52 moves in the sliding direction A through the slide of the first casing 3. Although the flexible printed circuit board 52 has been described as an example of the support member in the present embodiment, the support member is not limited thereto. The support member may be, for example, a sheet member and a rod member other than the flexible printed circuit board.

The flexible printed circuit board 51 is, as an example, cut out of a roll-shaped material in which a plurality of flexible printed circuit boards 51 are arranged. The flexible printed circuit board 52 is, as an example, cut out of a roll-shaped material in which a plurality of flexible printed circuit boards 52 are arranged. In the present embodiment, as an example, the flexible printed circuit board 51 and the flexible printed circuit board 52 have nearly the same structure. The flexible printed circuit boards 51 and 52 are in particular curved (curled) states in their free states. In the present embodiment, the folded-back portions 51e and 52e are provided in which the flexible printed circuit boards 51 and 52 are further curved so that the curvature of the flexible printed circuit boards 51 and 52 in the curved states becomes smaller than that in their free states. The flexible printed circuit board 51, therefore, has an elastic force in a direction that the extending portion 51c and the second extending portion 51d are separated from each other. The flexible printed circuit board 52 has an elastic force in a direction that the extending portion 52c and the extending portion 52d are separated from each other. Owing to the structure, the flexible printed circuit boards 51 and 52 are pressed against each other through the extending portions 51c and 52c.

The plate member 54 (a reinforcing member) is positioned in between the extending portion 51c of the flexible printed circuit board 51 and the extending portion 52c of the flexible printed circuit board 52. In other words, the plate member 54 is disposed in between the extending portions 51c and 52c. The plate member 54 is fixed to the extending portions 51c and 52c through, for example, adhesive. The plate member 54 is, as an example, provided across both ends 51h and 51i in the width direction of the flexible printed circuit board 51. The plate member 54 improves the rigidity of the extending portions 51c and 52c. The plate member 54 may be formed of, for example, metal such as stainless, resin, and ceramics.

The first casing 3 comprises an abutting portion 57 (a first abutting portion, abutting member, pressing portion, or pressing member) as illustrated in FIG. 4. The abutting portion 57 is, as an example, formed to have a plate-like shape and is positioned on the flexible printed circuit board 52 side of the display device 4 while being fixed to the display device 4. When the extending portion 52d of the flexible printed circuit board 52 becomes deformed toward the display device 4, the extending portion 52d is allowed to abut on the abutting portion 57. The extending portion 52d may abut on the abutting portion 57 at all times.

The second casing 2 comprises an abutting portion 58 (a second abutting portion, abutting member, pressing portion, or pressing member). The abutting portion 58 is, as an example, formed to have a plate-like shape and is positioned on the flexible printed circuit board 51 side of the circuit board 6 while being fixed to the second casing 2. When the extending portion 51d becomes deformed toward the circuit board 6, the extending portion 51d is allowed to abut on the abutting portion 58. The extending portion 51d may abut on the abutting portion 58 at all times.

In the present embodiment, as an example, the keyboard 7 functions as an inserted and removed portion (an intervening portion) that is inserted into and removed from between the flexible printed circuit board 51 and the flexible printed circuit board 52. In the present embodiment, as an example, the keyboard 7 is provided with a curved guide 7b. The guide 7b is provided on the far end of the keyboard 7. The guide 7b guides the flexible printed circuit board 52 when the keyboard 7 is inserted into between the flexible printed circuit board 51 and the flexible printed circuit board 52.

In the electronic device 1 of the above-described structure, when the electronic device 1 is in the opened state, as illustrated in FIG. 3, the extending portions 51c and 51d of the flexible printed circuit boards 51 and 52, respectively, are spaced apart from the keyboard 7. From that state, when the first casing 3 is slid with respect the second casing 2 so that the electronic device 1 shifts to the overlaid state (FIGS. 4 and 5), the keyboard 7 is inserted into between the extending portions 51c and 51d. Along with this, the folded-back portions 51e and the extending portion 51c are guided by the guide 7b to move toward the circuit board 6. Along with this slide, the flexible printed circuit board 51 is pushed by a force in the sliding direction A1 concerned. Along with this, as an example, the extending portion 51c of the flexible printed circuit board 51 is about to become deformed pushing the extending portion 52c of the flexible printed circuit board 52. However, the deformation is prevented because the extending portion 51c is pushed by the extending portion 52c of the flexible printed circuit board 52. To be more specific, as an example, the extending portion 52c tends to push to deform the extending portion 51c. In other words, deformation vectors occurring in the flexible printed circuit boards 51 and 52 (the extending portions 51c and 51d) are cancelled out. A pushing force is thereby stably exerted on the extending portions 51c and 51d in the direction along the sliding direction A1. Consequently, buckling and jamming in the flexible printed circuit board 51 are prevented.

As described above, in the electronic device 1 of the present embodiment, buckling and jamming in the flexible printed circuit board 51 can be prevented because the flexible printed circuit board 52 is overlaid on the flexible printed circuit board 51. Inconvenience such as damage hardly occurs in the flexible printed circuit board 51.

In the present embodiment, buckling and jamming in the extending portion 51c can be reduced because the plate member 54 is provided in between the extending portions 51c and 52c.

In the present embodiment, interference between the extending portions 51c and 52c and components around the electric connector 50 (the first casing 3, the second casing 2, or the like) can be reduced because the extending portions 51c and 52c are passed through the hole 53c of the fixing member 53.

In the present embodiment, characteristics such as thermal deformability and the like are nearly the same for the flexible printed circuit boards 51 and 52 because the pushing member is the flexible printed circuit board 52 in like manner with the flexible printed circuit board 51. Buckling and jamming in the flexible printed circuit board 51 can be therefore prevented by the flexible printed circuit board 52.

In the present embodiment, although the flexible printed circuit board 52 is provided as a dummy, the flexible printed circuit board 52 may electrically connect the electronic components.

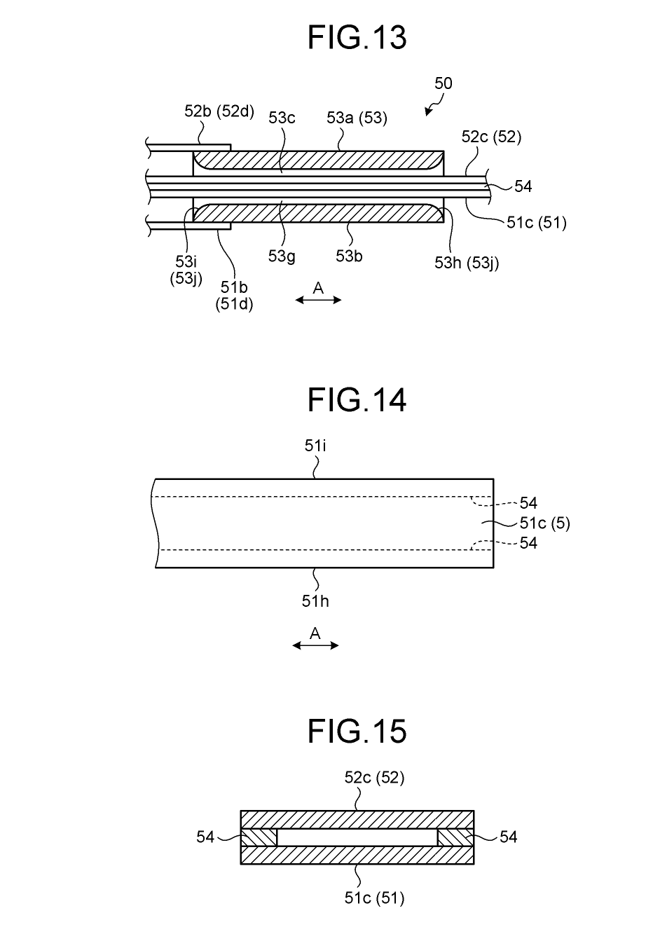

In a second embodiment, as illustrated in FIG. 13, in the fixing member 53, curve-shaped parts 53j (curved portions or guide portions) are provided at ends 53h and 53i of the inner periphery 53g of the hole 53c facing the flexible printed circuit board 51.

According to the second embodiment, when the flexible printed circuit boards 51 and 52 come into contact with the parts 53j of the inner periphery 53g by vibration and the like while moving through the hole 53c of the fixing member 53, damage to the flexible printed circuit boards 51 and 52 can be reduced because the parts 53j are formed in a curved shape.

In a third embodiment, as illustrated in FIGS. 14 and 15, the plate member 54 is provided at each of the ends 51h and 51i in the width direction of the flexible printed circuit board 51. In other words, two plate members 54 are provided. Also by such structure, buckling and jamming in the flexible printed circuit board 51 can be further prevented, as is the case with the first embodiment.

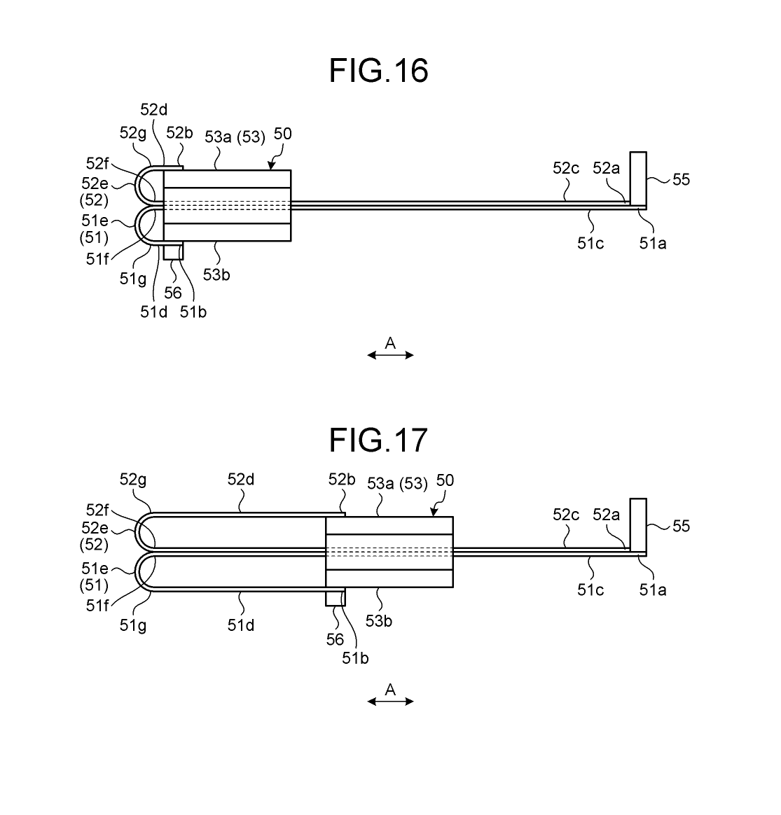

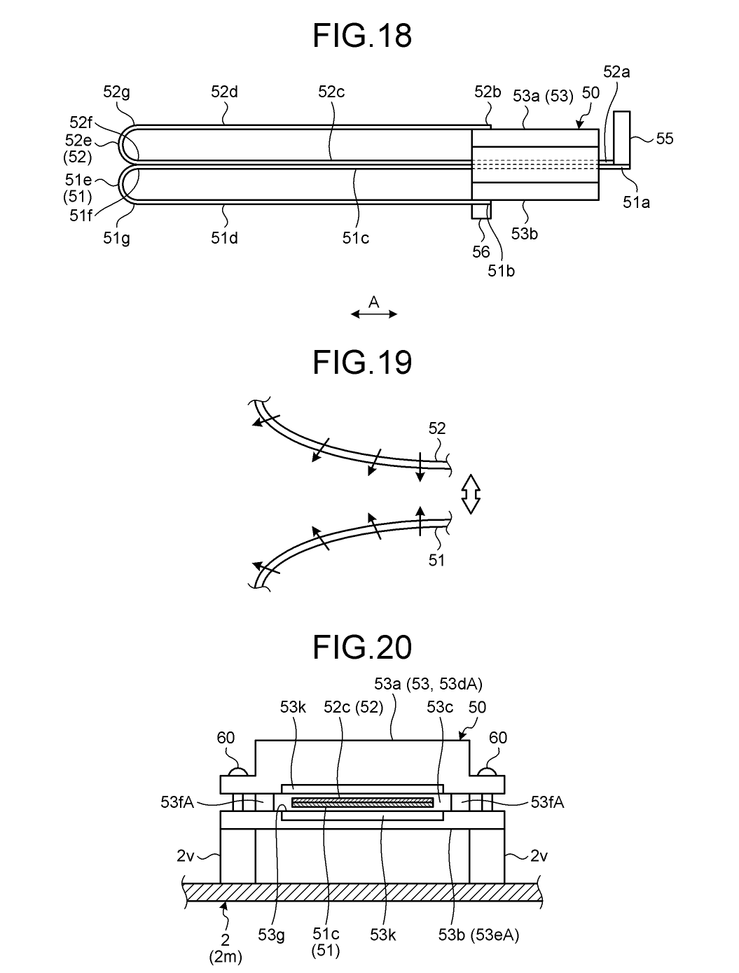

In a fourth embodiment, as illustrated FIGS. 16 to 19, the electric connector 50 is not provided with the plate member 54 of the first embodiment. Also by such structure, buckling and jamming in the flexible printed circuit board 51 can be prevented by the flexible printed circuit board 52.

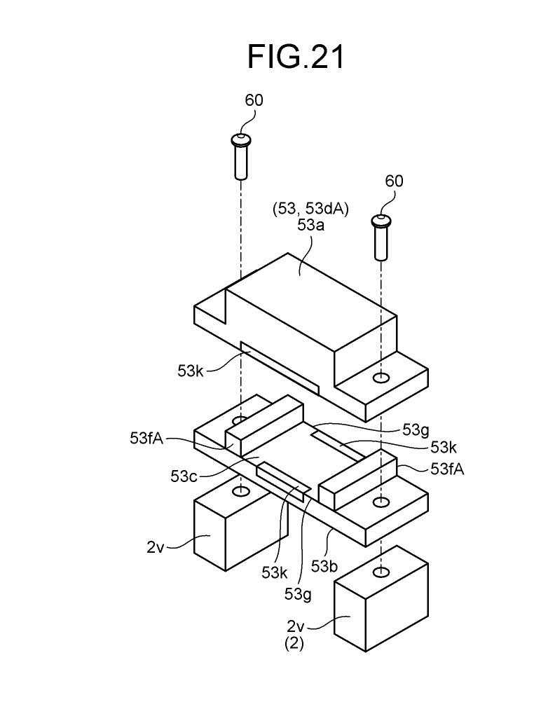

In a fifth embodiment, as illustrated in FIGS. 20 and 21, a first member 53dA comprising the surface 53a and a second member 53eA comprising the surface 53b of the fixing member 53 are fixed to a fixing portion 2v of the second casing 2 through a fixing member 60 (for example, a screw). The fixing member 53 has the hole 53c. A spacer 53fA is interposed in between the first member 53dA and the second member 53eA. In this structure, as an example, before the first member 53dA is attached to the second member 53eA, the flexible printed circuit boards 51 and 52 are positioned in between the first member 53dA and the second member 53eA. Thereafter, the first member 53dA is attached to the second member 53eA to fix the fixing member 53 to the first casing 3. The flexible printed circuit boards 51 and 52 can be thereby set to the fixing member 53 relatively easily. In the example in FIGS. 20 and 21, the plate member 54 is not provided.

In the present embodiment, a part 53k (an area or a cover) of which the friction coefficient is lower than that of its surroundings is provided at the ends 53h and 53i of the inner periphery 53g of the hole 53c facing the flexible printed circuit boards 51 and 52. The part 53k is, for example, a film formed of silicone and Teflon (registered trademark). In the present embodiment, as an example, the first member 53dA and the second member 53eA are, for example, resin or metal. The part 53k has a lower friction coefficient (a friction coefficient with respect to the flexible printed circuit boards 51 and 52) than those of the first member 53dA and the second member 53eA. In this structure, when the flexible printed circuit boards 51 and 52 come into contact with the part 53k of the inner periphery 53g by vibration and the like while moving through the hole 53c of a fixing member 53, damage to the flexible printed circuit boards 51 and 52 can be reduced because the friction coefficient of the part 53k is lower than that of its surroundings.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first casing comprising a first electronic component;
a second casing comprising a second electronic component, wherein the first casing is configured to be slidably connected to the second casing;
a first flexible printed circuit board comprising:
a first end fixed to the first casing and configured to be electrically connected to the first electronic component;
a second end fixed to the second casing and configured to be electrically connected to the second electronic component;
a first extending portion comprising the first end and provided along a sliding direction of the first casing with respect to the second casing;
a second extending portion comprising the second end, provided along the sliding direction, and arranged spaced apart from the first extending portion; and
a first folded-back portion with a curved shape, configured to connect an end of the first extending portion opposite the first end and an end of the second extending portion opposite the second end with each other; and
a pushing member comprising:
a third end fixed to the first casing;
a fourth end fixed to the second casing;
a third extending portion comprising the third end, provided along the sliding direction, and overlaid on the first extending portion at a side opposite the second extending portion;
a fourth extending portion comprising the fourth end, provided along the sliding direction, and arranged spaced apart from the third extending portion; and
a second folded-back portion with a curved shape, extending from an end of the third extending portion opposite the third end to an end of the fourth extending portion opposite the fourth end in a direction away from the first folded-back portion.

2. The electronic device of claim 1, wherein the pushing member is a second flexible printed circuit board.

3. The electronic device of claim 1, wherein
the first flexible printed circuit board comprises an elastic force in a direction in which the first extending portion and the second extending portion are separated from each other, and
the pushing member comprises an elastic force in a direction in which the third extending portion and the fourth extending portion are separated from each other.

4. The electronic device of claim 1, further comprising:
a plate member positioned in between the first extending portion and the third extending portion, wherein
the third extending portion is configured to be overlaid on the first extending portion at a side of the first extending portion opposite the second extending portion with the plate member interposed therebetween.

5. The electronic device of claim 4, wherein the plate member is provided across both ends in a width direction of the first flexible printed circuit board.

6. The electronic device of claim 4, wherein the plate member is provided at each of both ends in a width direction of the first flexible printed circuit board.

7. The electronic device of claim 1, further comprising a fixing member provided to the second casing, comprising a hole, wherein the first extending portion and the third extending portion pass through the hole, and the second end and the fourth end are fixed to the fixing member.

8. The electronic device of claim 7, wherein a curved part is provided to an end of an inner periphery of the hole facing the first flexible printed circuit board.

9. The electronic device of claim 7, wherein a part having a lower friction coefficient than that of surroundings is provided to an end of an inner periphery of the hole facing the first flexible printed circuit board.

10. An electric connector, comprising:
a flexible printed circuit board comprising:
a first end fixed to a first casing comprising first electronic component and configured to be electrically connected to the first electronic component;
a second end fixed to a second casing comprising a second electronic component, wherein the second end is configured to be electrically connected to the second electronic component, and the first casing is configured to be slidably connected to the second casing;
a first extending portion comprising the first end and provided along a sliding direction of the first casing with respect to the second casing;
a second extending portion comprising the second end, provided along the sliding direction, and arranged spaced apart from the first extending portion; and
a first folded-back portion with a curved shape, configured to connect an end of the first extending portion opposite the first end and an end of the second extending portion opposite the second end with each other; and
a pushing member comprising:
a third end fixed to the first casing;
a fourth end fixed to the second casing;
a third extending portion comprising the third end, provided along the sliding direction, and overlaid on the first extending portion at a side opposite the second extending portion;
a fourth extending portion comprising the fourth end, provided along the sliding direction, and arranged spaced apart from the third extending portion; and
a second folded-back portion with a curved shape, extending from an end of the third extending portion opposite the third end to an end of the fourth extending portion opposite the fourth end in a direction away from the first folded-back portion.
